(19) United States
(12) Patent Application Publication
(10) Pub. No.: US 2026/0045205 A1
(43) Pub. Date: Feb. 12, 2026

(54) GATE DRIVING CIRCUIT, DISPLAY DEVICE INCLUDING THE GATE DRIVING CIRCUIT AND ELECTRONIC DEVICE INCLUDING THE DISPLAY DEVICE

(71) Applicant: Samsung Display Co., Ltd., Yongin-si (KR)

(72) Inventors: Sanghun Kim, Yongin-si (KR); NACKHYEON KEUM, Yongin-si (KR); Yongchan Kim, Yongin-si (KR)

(21) Appl. No.: 19/212,441

(22) Filed: May 19, 2025

(30) Foreign Application Priority Data
Aug. 8, 2024 (KR) 10-2024-0105982

(51) Int. Cl. G09G 3/32

(52) U.S. Cl. CPC G09G 3/32; G09G 2310/0267; G09G 2310/0286; G09G 2310/08; G09G 2330/021

(57) ABSTRACT

A gate driver may include stages for outputting first and second gate signals, the stages including a control circuit configured to control a voltage of a pull-up control node and a voltage of a first pull-down control node in response to an input signal and a first clock signal, and configured to output a carry signal at a carry output node in response to the voltage of the pull-up control node or the voltage of the first pull-down control node, a first output circuit configured to output the first gate signal at a first output node in response to the voltage of the pull-up control node or a voltage of the carry output node, and a second output circuit configured to output the second gate signal at a second output node in response to the voltage of the pull-up control node or the voltage of the carry output node.

### CROSS-REFERENCE TO RELATED APPLICATION

The present application claims priority to, and the benefit of, Korean Patent Application No. 10-2024-0105982, filed on Aug. 8, 2024, in the Korean Intellectual Property Office, the entire disclosure of which is incorporated herein by reference.

### BACKGROUND

### 1. Field

Embodiments of the present disclosure relate to a gate driver, a display device including the gate driver, and an electronic device including the display device.

### 2. Description of the Related Art

Generally, a display device may include a display panel and a display panel driver. The display panel may include gate lines, data lines and pixels. The display panel driver may include a gate driver providing a gate signal to the gate lines, a data driver providing a data voltage to the data lines, and a driving controller controlling the gate driver and the driving controller.

The gate driver may include transistors. As the number of the transistors included in the gate driver increases, a power consumption of the display device and a dead space of the display device increase. In addition, as the number of the transistors increases in the same area, a size of the transistor decreases. As the size of the transistor decreases, a magnitude of a driving current may decrease and a rising time and a falling time of the gate signal output from the gate driver increase. Thus, the transistor may output a wrong output value.

Accordingly, when the gate driver includes a relatively large number of transistors, each of the transistors may suitably have a relatively small size, and thus, reliability of the gate driver may decrease.

### SUMMARY

An aspect of the present disclosure provides a gate driver having high stability and reliability while reducing a power consumption and a dead space of a display device.

Another aspect of the present disclosure provides a display device including the gate driver.

Still another aspect of the present disclosure provides an electronic device including the display device.

However, aspects of the present disclosure are not limited to the above objects, and may be variously extended without departing from the spirit and scope of the present disclosure.

According to embodiments, a gate driver of the present disclosure may include stages each outputting two or more gate signals. Each of the stages may include a control circuit configured to control a voltage of a pull-up control node and a voltage of a first pull-down control node in response to an input signal and a first clock signal, and configured to output a carry signal at a carry output node in response to the voltage of the pull-up control node and the voltage of the first pull-down control node, a first output circuit configured to output a first gate signal at a first output node in response to the voltage of the pull-up control node and a voltage of the carry output node, and a second output circuit configured to output a second gate signal at a second output node in response to the voltage of the pull-up control node and the voltage of the carry output node.

The control circuit may include a first transistor including a control electrode configured to receive the first clock signal, a first electrode configured to receive the input signal, and a second electrode connected to a buffer node, a second transistor including a control electrode connected to the buffer node, a first electrode configured to receive a first power supply voltage, and a second electrode connected to the pull-up control node, a third transistor including a control electrode, a first electrode connected to the pull-up control node, and a second electrode configured to receive a second power supply voltage, a fourth transistor including a control electrode configured to receive the second power supply voltage, a first electrode connected to the buffer node, and a second electrode connected to the first pull-down control node, a fifth transistor including a control electrode connected to the pull-up control node, a first electrode configured to receive the first power supply voltage, and a second electrode connected to the carry output node, a sixth transistor including a control electrode connected to the first pull-down control node, a first electrode connected to the carry output node, and a second electrode configured to receive the second power supply voltage, a first capacitor including a first electrode configured to receive the first power supply voltage, and a second electrode connected to the pull-up control node, and a second capacitor including a first electrode connected to the carry output node, and a second electrode connected to the first pull-down control node.

The control electrode of the third transistor may be connected to the first pull-down control node.

The control electrode of the third transistor may be connected to the buffer node.

The third transistor may include an N-channel metal oxide semiconductor (NMOS) transistor.

The first output circuit may include a seventh transistor including a control electrode configured to receive the second power supply voltage, a first electrode connected to the carry output node, and a second electrode connected to a second pull-down control node, an eighth transistor including a control electrode connected to the pull-up control node, a first electrode configured to receive the first power supply voltage, and a second electrode connected to the first output node, a ninth transistor including a control electrode connected to the second pull-down control node, a first electrode connected to the first output node, and a second electrode configured to receive a second clock signal, and a third capacitor including a first electrode connected to the first output node, and a second electrode connected to the second pull-down control node.

A ratio of a channel width to a channel length of at least one of the seventh transistor, the eighth transistor, or the ninth transistor may be different from a ratio of a channel width to a channel length of at least one of the first transistor, the second transistor, the third transistor, the fourth transistor, the fifth transistor, or the sixth transistor.

The ratio of the channel width to the channel length of the at least one of the seventh transistor, the eighth transistor, or the ninth transistor may be greater than the ratio of the channel width to the channel length of the at least one of the first transistor, the second transistor, the third transistor, the fourth transistor, the fifth transistor, or the sixth transistor.

The second output circuit may include a tenth transistor including a control electrode configured to receive the second power supply voltage, a first electrode connected to the carry output node, and a second electrode connected to a third pull-down control node, an eleventh transistor including a control electrode connected to the pull-up control node, a first electrode configured to receive the first power supply voltage, and a second electrode connected to the second output node, a twelfth transistor including a control electrode connected to the third pull-down control node, a first electrode connected to the second output node, and a second electrode configured to receive a third clock signal, and a fourth capacitor including a first electrode connected to the second output node, and a second electrode connected to the third pull-down control node.

A ratio of a channel width to a channel length of at least one of the tenth transistor, the eleventh transistor, or the twelfth transistor may be different from a ratio of a channel width to a channel length of at least one of the first transistor, the second transistor, the third transistor, the fourth transistor, the fifth transistor, or the sixth transistor.

The ratio of the channel width to the channel length of the at least one of the tenth transistor, the eleventh transistor, or the twelfth transistor may be greater than the ratio of the channel width to the channel length of the at least one of the first transistor, the second transistor, the third transistor, the fourth transistor, the fifth transistor, or the sixth transistor.

According to embodiments, a display device of the present disclosure may include a display panel including pixels, a data driver configured to provide data voltages to the display panel, a gate driver configured to provide gate signals to the display panel, and a driving controller configured to control the data driver and the gate driver. The gate driver may include stages each outputting two or more the gate signals.

Each of the stages may include a control circuit configured to control a voltage of a pull-up control node and a voltage of a first pull-down control node in response to an input signal and a first clock signal, and configured to output a carry signal at a carry output node in response to the voltage of the pull-up control node and the voltage of the first pull-down control node, a first output circuit configured to output a first gate signal at a first output node in response to the voltage of the pull-up control node and a voltage of the carry output node, and a second output circuit configured to output a second gate signal at a second output node in response to the voltage of the pull-up control node and the voltage of the carry output node.

The control circuit may include a first transistor including a control electrode configured to receive the first clock signal, a first electrode configured to receive the input signal, and a second electrode connected to a buffer node, a second transistor including a control electrode connected to the buffer node, a first electrode configured to receive a first power supply voltage, and a second electrode connected to the pull-up control node, a third transistor including a control electrode, a first electrode connected to the pull-up control node, and a second electrode configured to receive a second power supply voltage, a fourth transistor including a control electrode configured to receive the second power supply voltage, a first electrode connected to the buffer node, and a second electrode connected to the first pull-down control node, a fifth transistor including a control electrode connected to the pull-up control node, a first electrode configured to receive the first power supply voltage, and a second electrode connected to the carry output node, a sixth transistor including a control electrode connected to the first pull-down control node, a first electrode connected to the carry output node, and a second electrode configured to receive the second power supply voltage, a first capacitor including a first electrode configured to receive the first power supply voltage, and a second electrode connected to the pull-up control node, and a second capacitor including a first electrode connected to the carry output node, and a second electrode connected to the first pull-down control node.

The control electrode of the third transistor may be connected to the first pull-down control node.

The first output circuit may include a seventh transistor including a control electrode configured to receive the second power supply voltage, a first electrode connected to the carry output node, and a second electrode connected to a second pull-down control node, an eighth transistor including a control electrode connected to the pull-up control node, a first electrode configured to receive the first power supply voltage, and a second electrode connected to the first output node, a ninth transistor including a control electrode connected to the second pull-down control node, a first electrode connected to the first output node, and a second electrode configured to receive a second clock signal, and a third capacitor including a first electrode connected to the first output node and a second electrode connected to the second pull-down control node.

A ratio of a channel width to a channel length of at least one of the seventh transistor, the eighth transistor, or the ninth transistor may be different from a ratio of a channel width to a channel length of at least one of the first transistor, the second transistor, the third transistor, the fourth transistor, the fifth transistor, or the sixth transistor.

The second output circuit may include a tenth transistor including a control electrode configured to receive the second power supply voltage, a first electrode connected to the carry output node, and a second electrode connected to a third pull-down control node, an eleventh transistor including a control electrode connected to the pull-up control node, a first electrode configured to receive the first power supply voltage, and a second electrode connected to the second output node, a twelfth transistor including a control electrode connected to the third pull-down control node, a first electrode connected to the second output node, and a second electrode configured to receive a third clock signal, and a fourth capacitor including a first electrode connected to the second output node, and a second electrode connected to the third pull-down control node.

A ratio of a channel width to a channel length of at least one of the tenth transistor, the eleventh transistor, or the twelfth transistor may be different from a ratio of a channel width to a channel length of at least one of the first transistor, the second transistor, the third transistor, the fourth transistor, the fifth transistor, or the sixth transistor.

According to embodiments, an electronic device of the present disclosure may include a processor configured to output an input control signal and input image data, a display panel including pixels, a data driver configured to provide data voltages to the display panel, a gate driver configured to provide gate signals to the display panel, and a driving controller configured to control the data driver and the gate driver based on the input control signal and the input image data. The gate driver may include stages each outputting two or more the gate signals, and each of the stages may include a control circuit configured to control a voltage of a pull-up control node and a voltage of a first pull-down control node in response to an input signal and a first clock signal, and configured to output a carry signal at a carry output node in response to the voltage of the pull-up control node and the voltage of the first pull-down control node, a first output circuit configured to output a first gate signal at a first output node in response to the voltage of the pull-up control node and a voltage of the carry output node, and a second output circuit configured to output a second gate signal at a second output node in response to the voltage of the pull-up control node and the voltage of the carry output node.

Therefore, the gate driver, the display device, and the electronic device according to embodiments may decrease the number of transistors included in the gate driver by allowing the first output circuit and the second output circuit of the gate driver to share the control circuit, so that a power consumption and a dead space of the display device may decrease.

As the dead space of the display device decreases, a ratio of a channel width and a channel length of each of the transistors included in the first output circuit or the second output circuit of the gate driver may increase. Accordingly, a driving current of each of the transistors included in the gate driver may increase.

In addition, as the driving current of each of the transistors included in the gate driver increases, a rising time and a falling time of the gate signal output from the gate driver may decrease. Accordingly, each of the transistors included in the gate driver may output an accurate output value, so that stability and reliability of the gate driver may be improved.

However, aspects of the present disclosure are not limited to the above aspects, and may be variously extended without departing from the spirit and scope of the present disclosure.

### BRIEF DESCRIPTION OF THE DRAWINGS

The above and other aspects of the present disclosure will become more apparent by describing in detailed embodiments thereof with reference to the accompanying drawings, in which:

FIG. 1 is a block diagram illustrating a display device according to embodiments;

FIG. 2 is a block diagram illustrating one or more embodiments of a gate driver included in the display device of FIG. 1;

FIG. 3 is a block diagram illustrating a stage included in the gate driver of FIG. 2;

FIG. 4 is a circuit diagram illustrating one or more embodiments of the stage of FIG. 3;

FIG. 5 is a timing diagram illustrating an operation of the gate driver of FIG. 2;

FIG. 6 is a circuit diagram illustrating one or more embodiments of a pixel included in the display device of FIG. 1;

FIG. 7 is a circuit diagram illustrating one or more embodiments of the stage of FIG. 3;

FIG. 8 is a block diagram illustrating one or more embodiments of a gate driver included in the display device of FIG. 1;

FIG. 9 is a block diagram illustrating a stage included in the gate driver of FIG. 8;

FIG. 10 is a block diagram illustrating an electronic device according to embodiments; and

FIG. 11 is a diagram illustrating one or more embodiments in which the electronic device of FIG. 10 is implemented as a smart phone.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection.

For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

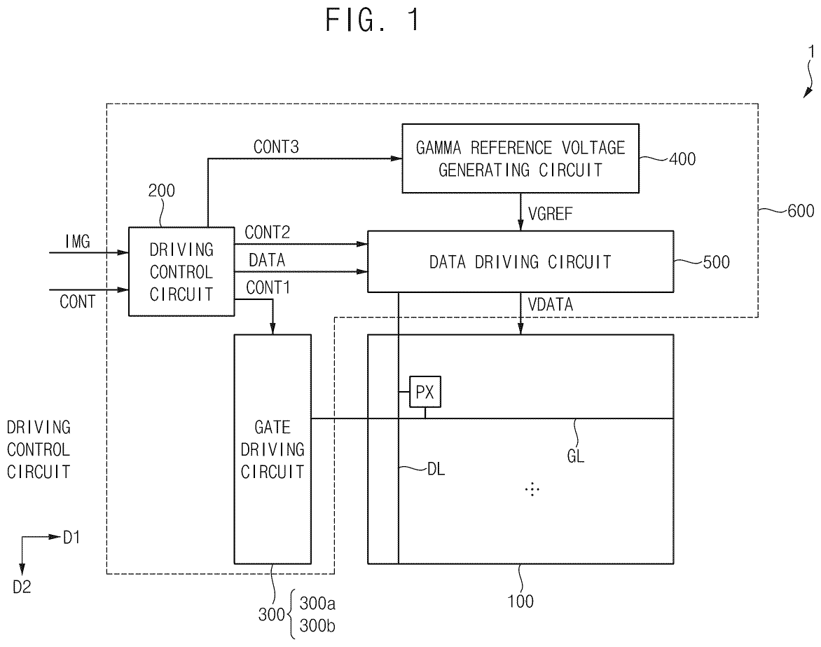

FIG. 1 is a block diagram illustrating a display device 1 according to embodiments.

Referring to FIG. 1, the display device 1 may include a display panel 100 and a display panel driver (e.g., display-panel-driving circuit) 600. The display panel driver 600 may include a driving controller (e.g., driving control circuit) 200, a gate driver (e.g., a gate-driving circuit) 300, a gamma reference voltage generator (e.g., a gamma reference voltage-generating circuit) 400, and a data driver (e.g., a data-driving circuit) 500.

For example, the driving controller 200 and the data driver 500 may be integrated into a single chip. For example, the driving controller 200, the gamma reference voltage generator 400, and the data driver 500 may be integrated into a single chip. A driving module including at least the driving controller 200 and the data driver 500 which are integrated into the single chip may be referred to as a timing controller embedded data driver (TED).

The display panel 100 may have a display region on which an image is displayed, and a peripheral region adjacent to the display region. For example, the peripheral region may be referred to as a bezel.

The display panel 100 may include gate lines GL and data lines DL, and also pixels PX electrically connected to the gate lines GL and to the data lines DL. The gate lines GL may extend in a first direction D1, and the data lines DL may extend in a second direction D2 crossing the first direction D1.

The driving controller 200 may receive input image data IMG and an input control signal CONT from an external device. For example, the input image data IMG may include red image data, green image data, and blue image data. In some embodiments, the input image data IMG may further include white image data. In another example, the input image data IMG may include magenta image data, yellow image data, and cyan image data. The input control signal CONT may include a master clock signal and a data enable signal. The input control signal CONT may further include a vertical synchronizing signal and a horizontal synchronizing signal.

The driving controller 200 may generate a gate control signal CONT1, a data control signal CONT2, a gamma control signal CONT3, and a data signal DATA based on the input image data IMG and the input control signal CONT.

The driving controller 200 may generate the gate control signal CONT1 for controlling an operation of the gate driver 300 based on the input control signal CONT, and may output the gate control signal CONT1 to the gate driver 300. The gate control signal CONT1 may include a vertical start signal and a gate clock signal.

The driving controller 200 may generate the data control signal CONT2 for controlling an operation of the data driver 500 based on the input control signal CONT, and may output the data control signal CONT2 to the data driver 500. The data control signal CONT2 may include a horizontal start signal and a load signal.

The driving controller 200 may generate the data signal DATA based on the input image data IMG. The driving controller 200 may output the data signal DATA to the data driver 500.

The driving controller 200 may generate the gamma control signal CONT3 for controlling an operation of the gamma reference voltage generator 400 based on the input control signal CONT, and may output the gamma control signal CONT3 to the gamma reference voltage generator 400.

The gate driver 300 may generate gate signals in response to the gate control signal CONT1 received from the driving controller 200. The gate driver 300 may output the gate signals to the gate lines GL. For example, the gate driver 300 may sequentially output the gate signals to the gate lines GL. For example, the gate driver 300 may be mounted on the peripheral region of the display panel 100. For example, the gate driver 300 may be integrated on the peripheral region of the display panel 100.

The gamma reference voltage generator 400 may generate a gamma reference voltage VGREF in response to the gamma control signal CONT3 received from the driving controller 200. The gamma reference voltage generator 400 may provide the gamma reference voltage VGREF to the data driver 500.

In one or more embodiments, the gamma reference voltage generator 400 may be located in the driving controller 200 or in the data driver 500.

The data driver 500 may receive the data control signal CONT2 and the data signal DATA from the driving controller 200, and may receive the gamma reference voltages VGREF from the gamma reference voltage generator 400. The data driver 500 may convert the data signal DATA in a digital form into data voltages in an analog form using the gamma reference voltages VGREF. The data driver 500 may output the data voltages to the data lines DL.

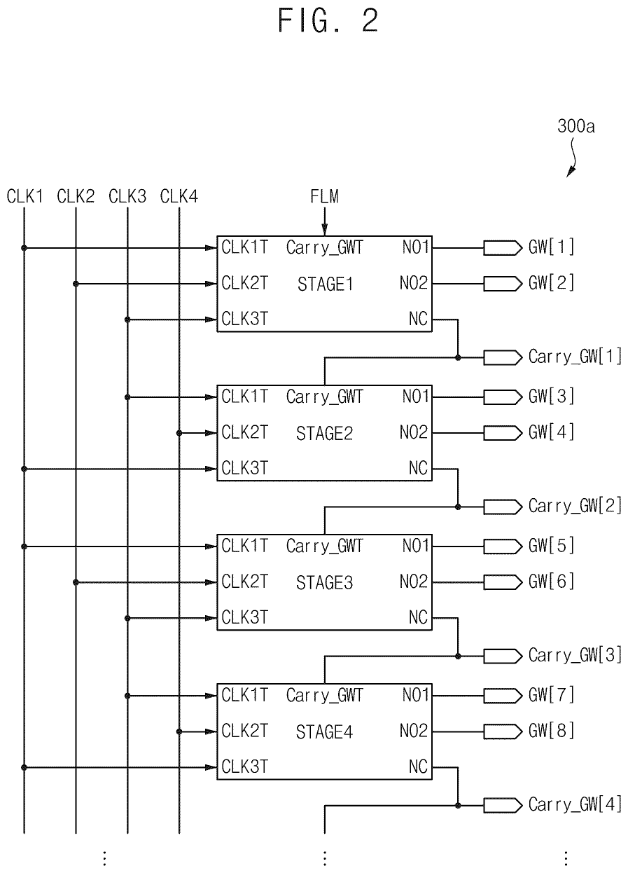

FIG. 2 is a block diagram illustrating one or more embodiments of the gate driver 300a included in the display device 1 of FIG. 1.

Referring to FIG. 2, the gate driver 300a may receive an input signal FLM or Carry_GW, a first clock signal CLK1, a second clock signal CLK2, a third clock signal CLK3, and a fourth clock signal CLK4, and may include stages STAGE1, STAGE2, STAGE3, STAGE4, . . . that sequentially output gate signals GW[1], GW[2], GW[3], GW[4], . . . to pixels PX. The input signal FLM or Carry_GW may be a start signal FLM or a carry signal Carry_GW of a previous stage.

Each of the stages STAGE1, STAGE2, STAGE3, STAGE4, . . . may output two gate signals GW.

For example, the first clock signal CLK1 may be applied to a first clock terminal CLK1T of a first stage STAGE1, the second clock signal CLK2 may be applied to a second clock terminal CLK2T of the first stage STAGE1, the third clock signal CLK3 may be applied to a third clock terminal CLK3T of the first stage STAGE1, and the start signal FLM may be applied to an input terminal Carry_GWT of the first stage STAGE1. The first stage STAGE1 may output a first gate signal GW[1], a second gate signal GW[2] and a first carry signal Carry_GW[1].

For example, the third clock signal CLK3 may be applied to a first clock terminal CLK1T of a second stage STAGE2, the fourth clock signal CLK4 may be applied to a second clock terminal CLK2T of the second stage STAGE2, the first clock signal CLK1 may be applied to a third clock terminal CLK3T of the second stage STAGE2, and the first carry signal Carry_GW[1] of the first stage STAGE1 may be applied to an input terminal Carry_GWT of the second stage STAGE2. The second stage STAGE2 may output a third gate signal GW[3], a fourth gate signal GW[4], and a second carry signal Carry_GW[2].

For example, the first clock signal CLK1 may be applied to a first clock terminal CLK1T of a third stage STAGE3, the second clock signal CLK2 may be applied to a second clock terminal CLK2T of the third stage STAGE3, the third clock signal CLK3 may be applied to a third clock terminal CLK3T of the third stage STAGE3, and the second carry signal Carry_GW[2] may be applied to an input terminal Carry_GWT of the third stage STAGE3. The third stage STAGE3 may output a fifth gate signal GW[5], a sixth gate signal GW[6], and a third carry signal Carry_GW[3].

For example, the third clock signal CLK3 may be applied to a first clock terminal CLK1T of a fourth stage STAGE4, the fourth clock signal CLK4 may be applied to a second clock terminal CLK2T of the fourth stage STAGE4, the first clock signal CLK1 may be applied to a third clock terminal CLK3T of the fourth stage STAGE4, and the third carry signal Carry_GW[3] of the third stage STAGE3 may be applied to an input terminal Carry_GWT of the fourth stage STAGE4. The fourth stage STAGE4 may output a seventh gate signal GW[7], an eighth gate signal GW[8], and a fourth carry signal Carry_GW[4].

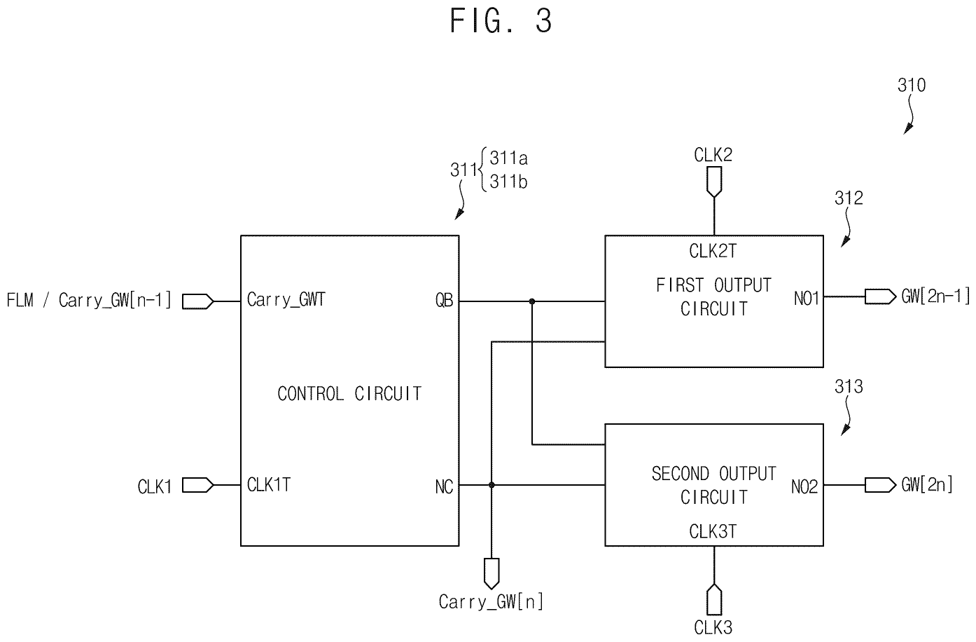

FIG. 3 is a block diagram illustrating a stage 310 included in the gate driver 300a of FIG. 2.

Referring to FIG. 3, the stage 310 may include a control circuit 311, a first output circuit 312, and a second output circuit 313.

The control circuit 311 may receive the first clock signal CLK1 or the third clock signal CLK3 at the first clock terminal CLK1T. For convenience of explanation, the first clock signal CLK1 is shown to be applied to the first clock terminal CLK1T in FIG. 3. For example, the control circuit 311 of an odd stage STAGE1, STAGE3, . . . may receive the first clock signal CLK1 at the first clock terminal CLK1T, and the control circuit of an even stage STAGE2, STAGE4, . . . may receive the third clock signal CLK3 at the first clock terminal CLK1T.

The control circuit 311 may receive a previous carry signal Carry_GW[n−1] that is the carry signal Carry_GW of the previous stage at the input terminal Carry_GWT or may receive the start signal FLM at the input terminal Carry_GWT. For example, the control circuit 311 of the first stage STAGE1 may receive the start signal FLM at the input terminal Carry_GWT. For example, the control circuit 311 of the n-th stage, where n is an integer greater than or equal to 2, may receive the previous carry signal Carry_GW[n−1] at the input terminal Carry_GWT.

A carry output node NC of the control circuit 311 may be connected to the first output circuit 312 and to the second output circuit 313. The carry output node NC of the control circuit 311 may output the carry signal Carry_GW[n].

The first output circuit 312 may receive the second clock signal CLK2 or the fourth clock signal CLK4 at the second clock terminal CLK2T. For convenience of explanation, the second clock signal CLK2 is shown to be applied to the second clock terminal CLK2T in FIG. 3. For example, the control circuit 311 of the odd stage STAGE1, STAGE3, . . . may receive the second clock signal CLK2 at the second clock terminal CLK2T, and the control circuit of the even stage STAGE2, STAGE4, . . . may receive the fourth clock signal CLK4 at the second clock terminal CLK2T.

The first output circuit 312 may output the first gate signal GW[2n−1] at a first output node NO1 based on the clock signal CLK2 or CLK4 that is applied to the second clock terminal CLK2T, a voltage of a pull-up control node QB, and a voltage of the carry output node NC.

The second output circuit 313 may receive the third clock signal CLK3 or the first clock signal CLK1 at the third clock terminal CLK3T. For convenience of explanation, the third clock signal CLK3 is shown to be applied to the third clock terminal CLK3T in FIG. 3. For example, the control circuit 311 of the odd stage STAGE1, STAGE3, . . . may receive the third clock signal CLK3 at the third clock terminal CLK3T, and the control circuit of the even stage STAGE2, STAGE4, . . . may receive the first clock signal CLK1 at the third clock terminal CLK3T.

The second output circuit 313 may output the second gate signal GW[2n] at the second output node NO2 based on the clock signal CLK3 or CLK1, the voltage of the pull-up control node QB, and the voltage of the carry output node NC.

As the first output circuit 312 and the second output circuit 313 share the control circuit 311, the display device 1 may decrease the number of control circuits 311 included in the gate driver 300a. As the number of the control circuits 311 included in the gate driver 300a decreases, the number of transistors included in the gate driver 300a may decrease. In addition, as the number of the transistors included in the gate driver 300a decreases, a power consumption of the display device 1 may decrease.

Further, as the number of the transistors included in the gate driver 300a decreases, a dead space of the display device 1 may decrease. As the dead space of the display device 1 decreases, a ratio W/L of a channel width to a channel length of each of the transistors included in the first output circuit 312 or the second output circuit 313 may increase. Accordingly, a driving current of each of the transistors included in the gate driver 300a may increase.

In addition, as the driving current of each of the transistors included in the gate driver 300a increases, a rising time and a falling time of the gate signal GW output from the gate driver 300a may decrease. Accordingly, each of the transistors included in the gate driver 300a may output an accurate output value, so that stability and reliability of gate driver 300a may be improved.

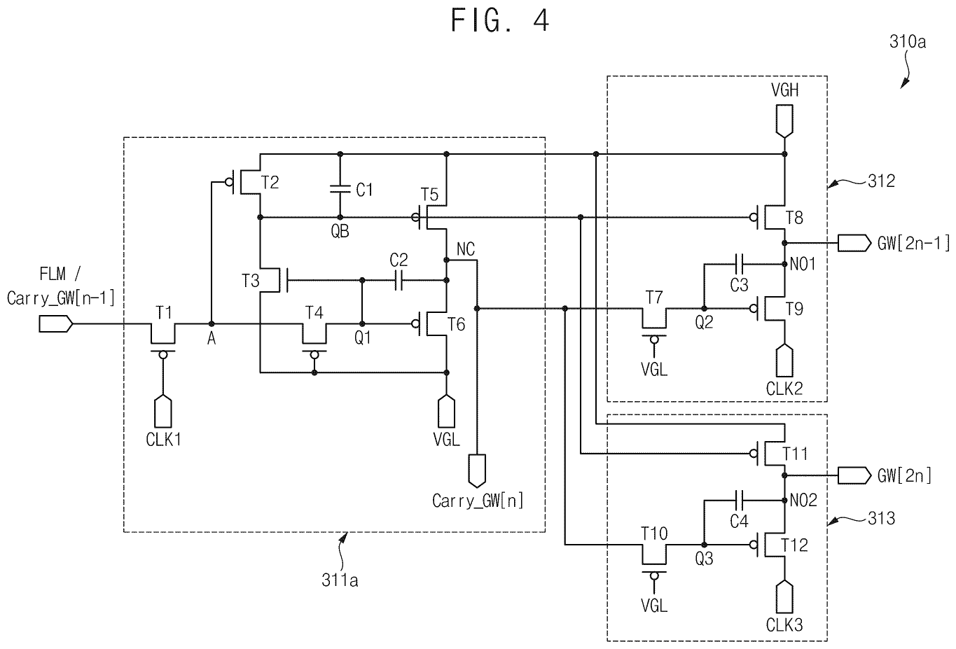

FIG. 4 is a circuit diagram illustrating one or more embodiments of the stage 310 of FIG. 3.

Referring to FIG. 4, the stage 310 may include a control circuit 311a, the first output circuit 312, and the second output circuit 313.

The control circuit 311a may control the voltage of the pull-up control node QB and a voltage of a first pull-down control node Q1 in response to the input signal FLM or Carry GW[n−1] and the first clock signal CLK1.

A voltage level of a second power supply voltage VGL may be lower than a voltage level of first power supply voltage VGH. For example, the first power supply voltage VGH may be a voltage having a high voltage level, the second power supply voltage VGL may be a voltage having a low voltage level that is lower than the high voltage level.

The control circuit 311a may output the carry signal Carry_GW[n] at the carry output node NC in response to the voltage of pull-up control node QB and a voltage of the first pull-down control node Q1.

The control circuit 311a may include a first transistor T1, a second transistor T2, a third transistor T3, a fourth transistor T4, a fifth transistor T5, a sixth transistor T6, a first capacitor C1, and a second capacitor C2.

The first transistor T1 may include a control electrode for receiving the first clock signal CLK1, a first electrode for receiving the input signal FLM or Carry_GW[n−1], and a second electrode connected to a buffer node A. When the first clock signal CLK1 has an activation level (e.g. a low level), the first transistor T1 may be turned on, and may transmit the input signal FLM or Carry_GW[n−1] to the buffer node A. second transistor T2 may include a control electrode connected to the buffer node A, a first electrode for receiving the first power supply voltage VGH, and a second electrode connected to the pull-up control node QB. When the second transistor T2 is turned on in response to a voltage of the buffer node A, the second transistor T2 may transmit the first power supply voltage VGH to the pull-up control node QB. For example, when the voltage of the buffer node A has a low voltage level, the second transistor T2 may transmit the first power supply voltage VGH to the pull-up control node QB.

The third transistor T3 may include a control electrode connected to the first pull-down control node Q1, a first electrode connected to the pull-up control node QB, and a second electrode for receiving the second power supply voltage VGL. When the third transistor T3 is turned on in response to the voltage of the first pull-down control node Q1, the third transistor T3 may transmit the second power supply voltage VGL to the pull-up control node QB. For example, the voltage of the first pull-down control node Q1 has the high voltage level, the third transistor T3 may transmit the second power supply voltage VGL to the pull-up control node QB.

A type of the third transistor may be different from a type of each of the first transistor T1, the second transistor T2, the fourth transistor T4, the fifth transistor T5, and the sixth transistor T6. For example, each of the first transistor T1, the second transistor T2 and the fourth to sixth transistors T4, T5, and T6 may be implemented as a P-channel metal oxide semiconductor (PMOS) transistor, and the third transistor T3 may be implemented as an N-channel metal oxide semiconductor (NMOS) transistor.

The fourth transistor T4 may include a control electrode for receiving the second power supply voltage VGL, a first electrode connected to the buffer node A, and a second electrode connected to the first pull-down control node Q1.

When the voltage of the first pull-down control node Q1 is bootstrapped, a channel current of the fourth transistor T4 may be zero. The fourth transistor T4 may be turned off while the voltage of the first pull-down control node Q1 is bootstrapped, and an electrical connection between the buffer node A and a control electrode of the sixth transistor T6 may be disconnected. On the other hand, the fourth transistor T4 may be turned on while the voltage of the first pull-down control node Q1 is not bootstrapped, the fourth transistor T4 may electrically connect the buffer node A and the control electrode of the sixth transistor T6.

The fifth transistor T5 may include a control electrode connected to the pull-up control node QB, a first electrode for receiving the first power supply voltage VGH, and a second electrode connected to the carry output node NC. When the fifth transistor T5 is turned on in response to the voltage of the pull-up control node QB, the fifth transistor T5 may transmit the first power supply voltage VGH to the carry output node NC. For example, when the voltage of the pull-up control node QB has the low voltage level, the fifth transistor T5 may transmit the first power supply voltage VGH to the carry output node NC. The carry signal Carry_GW[n] having a high level may be output from the carry output node NC.

The sixth transistor T6 may include the control electrode connected to the first pull-down control node Q1, a first electrode connected to the carry output node NC, and a second electrode for receiving the second power supply voltage VGL. When the sixth transistor is turned on in response to the voltage of the first pull-down control node Q1, the sixth transistor T6 may transmit the second power supply voltage VGL to the carry output node NC. For example, when the voltage of the first pull-down control node Q1 has the low voltage level, the sixth transistor may transmit the second power supply voltage VGL to the carry output node NC. The carry signal Carry_GW[n] having the low level may be output from the carry output node NC.

The first capacitor C1 may include a first electrode for receiving the first power supply voltage VGH, and a second electrode connected to the pull-up control node QB. The first capacitor C1 may store a difference between the first power supply voltage VGH and the voltage of the pull-up control node QB.

The second capacitor C2 may include a first electrode connected to the carry output node NC, and a second electrode connected to the first pull-down control node Q1. When the carry signal Carry_GW[n] is changed from the first power supply voltage VGH to the second power supply voltage VGL, the second capacitor C2 may bootstrap the voltage of the first pull-down control node Q1 based on the change of the voltage of the carry output node NC.

The first output circuit 312 may be connected to the pull-up control node QB of the control circuit 311a and the carry output node NC of the control circuit 311a.

The first output circuit 312 may include a seventh transistor T7, an eighth transistor, a ninth transistor T9, and a third capacitor C3.

The seventh transistor T7 may include a control electrode for receiving the second power supply voltage VGL, a first electrode connected to the carry output node NC, and a second electrode connected to a second pull-down control node Q2.

When a voltage of the second pull-down control node Q2 is bootstrapped, a channel current of the seventh transistor T7 may be zero. The seventh transistor T7 may be turned off while the voltage of the second pull-down control node Q2 is bootstrapped, and an electrical connection between the carry output node NC and a control electrode of the ninth transistor T9 may be disconnected. On the other hand, the seventh transistor T7 may be turned on while the voltage of the second pull-down control node Q2 is not bootstrapped, the seventh transistor T7 may electrically connect the carry output node NC and the control electrode of the ninth transistor T9.

The eighth transistor T8 may include a control electrode connected to the pull-up control node QB, a first electrode for receiving the first power supply voltage VGH, and a second electrode connected to the first output node NO1. When the eighth transistor T8 is turned on in response to the voltage of the pull-up control node QB, the eighth transistor T8 may transmit the first power supply voltage VGH to the first output node NO1. For example, when the voltage of the pull-up control node QB has the low voltage level, the eighth transistor T8 may transmit the first power supply voltage VGH to the first output node NO1. The first gate signal GW[2n−1] having the high level may be output from the first output node NO1.

The ninth transistor T9 may include the control electrode connected to the second pull-down control node Q2, a first electrode connected to the first output node NO1, and a second electrode for receiving the second clock signal CLK2. When the ninth transistor T9 is turned on in response to the voltage of the second pull-down control node Q2, the ninth transistor T9 may transmit the second clock signal CLK2 to the first output node NO1. For example, when the voltage of the second pull-down control node Q2 has the low voltage level, the ninth transistor T9 may transmit the second clock signal CLK2 to the first output node NO1. The first gate signal GW[2n−1] that is equal to the second clock signal CLK2 may be output from the first output node NO1.

The third capacitor C3 may include a first electrode connected to the first output node NO1 and a second electrode connected to the second pull-down control node Q2. When a level of the second clock signal CLK2 is changed from the high level to the low level, the third capacitor C3 may bootstrap the voltage of the second pull-down control node Q2 based on a change of a voltage of the first output node NO1.

The dead space of the display device 1 may decrease as the number of the transistors included in the gate driver 300a decreases (e.g., as compared to a conventional gate driver). In addition, a ratio W/L of a channel width to a channel length of at least one of the seventh to ninth transistors T7, T8, or T9 may be adjusted by as much as the dead space of the display device 1 decreases.

The ratio W/L of the channel width to the channel length of the at least one of the seventh to ninth transistors T7, T8, or T9 may be different from a ratio W/L of a channel width to a channel length of at least one of the first to sixth transistors T1, T2, T3, T4, T5, or T6. For example, the ratio W/L of the channel width to the channel length of the at least one of the seventh to ninth transistors T7, T8, or T9 may be greater than the ratio W/L of the channel width to the channel length of the at least one of the first to sixth transistors T1, T2, T3, T4, T5, or T6.

When the ratio W/L of the channel width to the channel length of the at least one of the seventh to ninth transistors T7, T8, or T9 is greater than the ratio W/L of the channel width to the channel length of the at least one of the first to sixth transistors T1, T2, T3, T4, T5, or T6, a magnitude of a current flowing through the seventh to ninth transistors T7, T8, and T9 may increase. When the magnitude of the current flowing through the seventh to ninth transistors T7, T8, and T9 increases, the rising time of the first gate signal GW[2n−1] and the falling time of the first gate signal GW[2n−1] may decrease, and thus, the first gate signal GW[2n−1] may be output stably.

The second output circuit 313 may be connected to the pull-up control node QB of the control circuit 311a and the carry output node NC of the control circuit 311a.

The second output circuit 313 may include a tenth transistor T10, an eleventh transistor T11, and a fourth capacitor C4.

The tenth transistor T10 may include a control electrode for receiving the second power supply voltage VGL, a first electrode connected to the carry output node NC, and a second electrode connected to a third pull-down control node Q3.

When a voltage of the third pull-down control node Q3 is bootstrapped, a channel current of the tenth transistor T10 may be zero. The tenth transistor T10 may be turned off while the voltage of the third pull-down control node Q3 is bootstrapped, and an electrical connection between the carry output node NC and a control electrode of the twelfth transistor T12 may be disconnected. On the other hand, the tenth transistor T10 may be turned on while the voltage of the third pull-down control node Q3 is not bootstrapped, and the tenth transistor T10 may electrically connect the carry output node NC and the control electrode of the twelfth transistor T12.

The eleventh transistor T11 may include a control electrode connected to the pull-up control node QB, a first electrode for receiving the first power supply voltage VGH, and a second electrode connected to the second output node NO2. When the eleventh transistor T11 is turned on in response to the voltage of the pull-up control node QB, the eleventh transistor T11 may transmit the first power supply voltage VGH to the second output node NO2. For example, when the voltage of the pull-up control node QB has the low voltage level, the eleventh transistor T11 may transmit the first power supply voltage VGH to the second output node NO2. The second gate signal GW[2n] having the high level may be output from the second output node NO2.

The twelfth transistor may include the control electrode connected to the third pull-down control node Q3, a first electrode connected to the second output node NO2, and a second electrode for receiving the third clock signal CLK3. When the twelfth transistor T12 is turned on in response to the voltage of the third pull-down control node Q3, the twelfth transistor T12 may transmit the third clock signal CLK3 to the second output node NO2. For example, when the voltage of the third pull-down control node Q3 has the low voltage level, the twelfth transistor T12 may transmit the third clock signal CLK3 to the second output node NO2. The second gate signal GW[2n] that is equal to the third clock signal CLK3 may be output from the second output node NO2.

The fourth capacitor C4 may include a first electrode connected to the second output node NO2, and a second electrode connected to the third pull-down control node Q3. When a level of the third clock signal CLK3 is changed from the high level to the low level, the fourth capacitor C4 may bootstrap the voltage of the third pull-down control node Q3 based on a change of a voltage of the second output node NO2.

The dead space of the display device 1 may decrease as the number of the transistors included in the gate driver 300a decreases (e.g., as compared to a conventional gate driver). In addition, a ratio W/L of a channel width to a channel length of at least one of the tenth to twelfth transistors T10, T11, or T12 may be adjusted by as much as the dead space of the display device 1 decreases.

The ratio W/L of the channel width to the channel length of the at least one of the tenth to twelfth transistors T10, T11, or T12 may be different from the ratio W/L of the channel width to the channel length of the at least one of the first to sixth transistors T1, T2, T3, T4, T5, or T6. For example, The ratio W/L of the channel width to the channel length of the at least one of the tenth to twelfth transistors T10, T11, or T12 may be greater than the ratio W/L of the channel width to the channel length of the at least one of the first to sixth transistors T1, T2, T3, T4, T5, or T6.

When the ratio W/L of the channel width to the channel length of the at least one of the tenth to twelfth transistors T10, T11, or T12 is greater than the ratio W/L of the channel width to the channel length of the at least one of the first to sixth transistors T1, T2, T3, T4, T5, or T6, a magnitude of a current flowing through the tenth to twelfth transistors T10, T11, and T12 may increase. When the magnitude of the current flowing through the tenth to twelfth transistors T10, T11, and T12 increases, the rising time of the second gate signal GW[2n] and the falling time of the second gate signal GW[2n] may decrease, and thus, the second gate signal GW[2n] may be output stably.

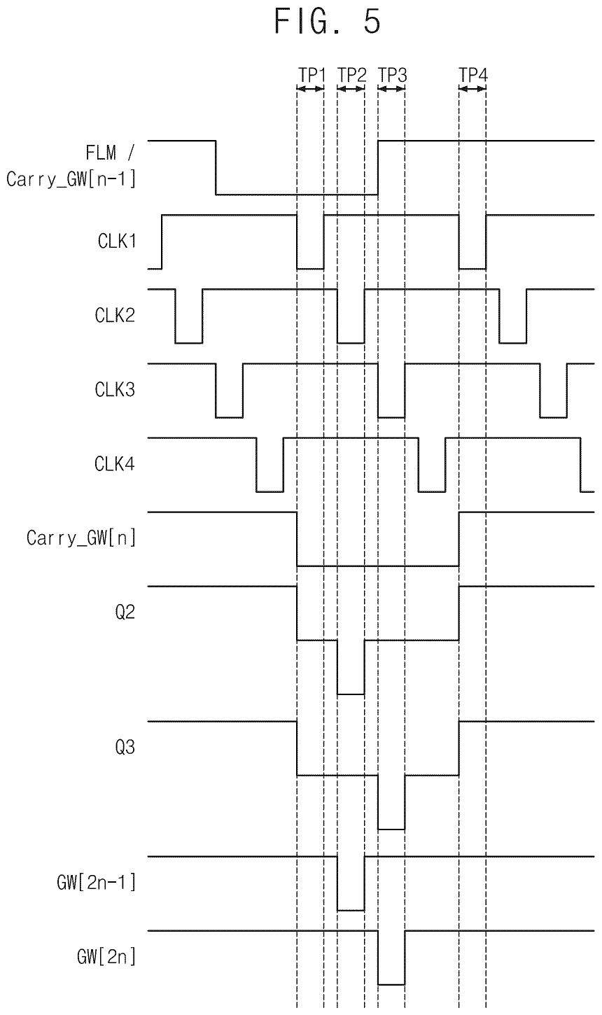

FIG. 5 is a timing diagram illustrating an operation of the gate driver 300a of FIG. 2.

Referring to FIG. 5, periods in which signals are applied to the gate driver 300a may include a first period TP1, a second period TP2, a third period TP3, and a fourth period TP4.

In the first period TP1, the input signal FLM or Carry_GW[n−1] and the first clock signal CLK1 may have the low level. The second clock signal CLK2, the third clock signal CLK3, and the fourth clock signal CLK4 may have the high level.

In the first period TP1, the first transistor may be turned on based on the first clock signal CLK1 having the low level. Accordingly, the input signal FLM or Carry_GW[n−1] may be transmitted to the buffer node A. The input signal FLM or Carry_GW[n−1] may be transmitted from the buffer node A to the first pull-down control node Q1 through the fourth transistor T4, and the voltage of the first pull-down control node Q1 may have the low voltage level. The sixth transistor T6 may be turned on in response to the voltage of the first pull-down control node Q1. The second power supply voltage VGL may be transmitted to the carry output node NC. The carry output node NC may output the carry signal Carry_GW[n] having the low level.

The seventh transistor T7 may transmit the voltage of the carry output node NC to the second pull-down control node Q2, and the voltage of the second pull-down control node Q2 may have the low voltage level. The ninth transistor T9 may be turned on in response to the voltage of the second pull-down control node Q2. The ninth transistor T9 may transmit the second clock signal CLK2 to the first output node NO1. The first gate signal GW[2n−1] having the high level may be output from the first output node NO1.

The tenth transistor T10 may transmit the voltage of the carry output node NC to the third pull-down control node Q3. The voltage of the third pull-down control node Q3 may have the low voltage level. The twelfth transistor T12 may be turned on in response to the voltage of the third pull-down control node Q3. The twelfth transistor T12 may transmit the third clock signal CLK3 to the second output node NO2. The second gate signal GW[2n] having the high level may be output from the second output node NO2.

In the second period TP2, the input signal FLM or Carry_GW[n−1] and the second clock signal CLK2 may have the low level. In addition, the first clock signal CLK1, the third clock signal CLK3, and the fourth clock signal CLK4 may have the high level.

In the second period TP2, when the ninth transistor T9 is turned on, the ninth transistor T9 may transmit the second clock signal CLK2 having the low level to the first output node NO1. The first gate signal GW[2n−1] having the low level may be output from the first output node NO1.

In the second period TP2, when the twelfth transistor T12 is turned on, the twelfth transistor T12 may transmit the third clock signal CLK3 having the high level to the second output node NO2. The second gate signal GW[2n] having the high level may be output from the second output node NO2.

In the third period TP3, the third clock signal CLK3 may have the low level. In addition, the input signal FLM or Carry_GW[n−1], the first clock signal CLK1, the second clock signal CLK2, and the fourth clock signal CLK4 may have the high level.

In the third period TP3, when the ninth transistor T9 is turned on, the ninth transistor T9 may transmit the second clock signal CLK2 having the high level to the first output node NO1. The first gate signal GW[2n−1] having the high level may be output from the first output node NO1.

In the third period TP3, when the twelfth transistor T12 is turned on, the twelfth transistor T12 may transmit the third clock signal CLK3 having the low level to the second output node NO2. The second gate signal GW[2n] having the low level may be output from the second output node NO2.

In the fourth period TP4, the first clock signal CLK1 may have the low level. In addition, the input signal FLM or Carry_GW[n−1], the second clock signal CLK2, the third clock signal CLK3, and the fourth clock signal CLK4 may have the high level.

In the fourth period TP4, the first transistor T1 may be turned on in response to the first clock signal CLK1 having the high level. The input signal FLM or Carry_GW[n−1] may be transmitted to the buffer node A. The input signal FLM or Carry_GW[n−1] may be transmitted from the buffer node A to the first pull-down control node Q1 through the fourth transistor T4, and the voltage of the first pull-down control node Q1 may have the high voltage level. The third transistor T3 may be turned on in response to the voltage of the first pull-down control node Q1. The third transistor T3 may transmit the second power supply voltage VGL to the pull-up control node QB. The voltage of the pull-up control node QB may have the low voltage level. The fifth transistor may be turned on in response to the voltage of the pull-up control node QB. The fifth transistor T5 may transmit the first power supply voltage VGH to the carry output node NC. The voltage of the carry output node NC may have the high voltage level. The carry output signal Carry_GW[n] having the high level may be output from the carry output node NC.

The eighth transistor T8 may be turned on in response to the voltage of the pull-up control node QB. The eighth transistor T8 may transmit the first power supply voltage VGH to the first output node NO1. The first gate signal GW[2n−1] having the high level may be output from the first output node NO1.

The eleventh transistor T11 may be turned on in response to the voltage of the pull-up control node QB. The eleventh transistor T11 may transmit the first power supply voltage VGH to the second output node NO2. The second gate signal GW[2n] having the high level may be output from the second output node NO2.

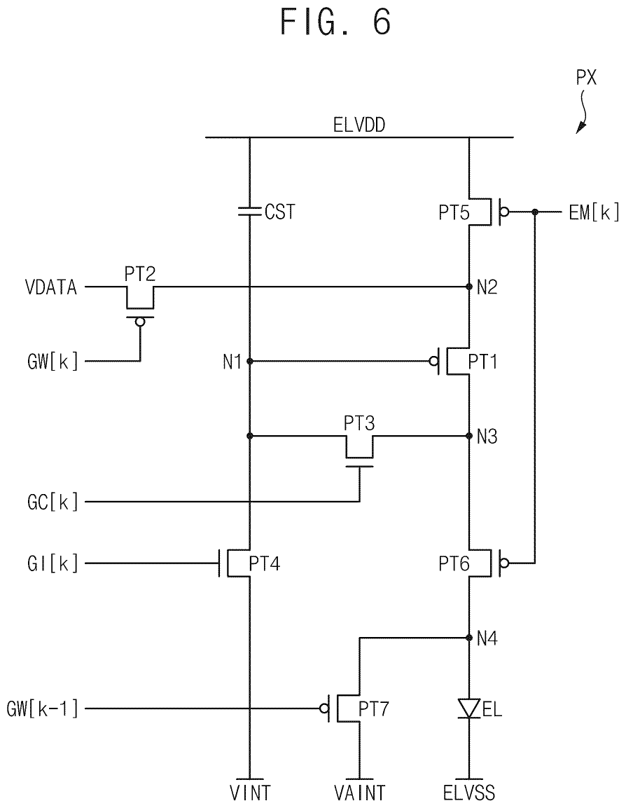

FIG. 6 is a circuit diagram illustrating one or more embodiments of a pixel PX included in the display device 1 of FIG. 1.

Referring to FIG. 6, the pixel PX may include first to seventh pixel transistors PT1 to PT7, a storage capacitor CST, and a light-emitting element EL. The pixel PX illustrated in FIG. 6 is assumed to be connected to a k-th gate line, where k is an integer between 1 and 2n.

The first pixel transistor PT1 may include a control electrode connected to a first node N1, a first electrode connected to a second node N2, and a second electrode connected to a third node N3. The first pixel transistor PT1 may generate a driving current corresponding to the data voltage VDATA.

The second pixel transistor PT2 may include a control electrode for receiving a data writing gate signal GW[k], a first electrode for receiving the data voltage VDATA, and a second electrode connected to the second node N2. When the second pixel transistor PT2 is turned on in response to the data writing gate signal GW[k], the second pixel transistor PT2 may provide the data voltage VDATA to the second node N2.

The third pixel transistor PT3 may include a control electrode for receiving a compensation gate signal GC[k], a first electrode connected to the third node N3, and a second electrode connected to the first node N1. When the third pixel transistor PT3 is turned on in response to the compensation gate signal GC[k], the third pixel transistor PT3 may diode-connect the first pixel transistor PT1.

The fourth pixel transistor PT4 may include a control electrode for receiving an initialization gate signal GI[k], a first electrode for receiving an initialization voltage VINT, and a second electrode connected to the first node N1. When the fourth pixel transistor PT4 is turned on in response to the initialization gate signal GI[k], the fourth pixel transistor PT4 may provide the initialization voltage VINT to the first node N1.

The fifth pixel transistor PT5 may include a control electrode for receiving an emission signal EM[k], a first electrode for receiving a first driving voltage ELVDD, and a second electrode connected to the second node N2.

The sixth pixel transistor PT6 may include a control electrode for receiving the emission signal EM[k], a first electrode connected to the third node N3, and a second electrode connected to a fourth node N4.

The fifth pixel transistor PT5 and the sixth pixel transistor PT6 may control a light emission of the light-emitting element EL in response to the emission signal EM[k].

The seventh pixel transistor PT7 may include a control electrode for receiving a previous data writing gate signal GW[k−1], a first electrode for receiving an anode initialization voltage VAINT, and a second electrode connected to the fourth node N4. When the seventh pixel transistor PT7 is turned on in response to the previous data writing gate signal GW[k−1], the seventh pixel transistor PT7 may provide the anode initialization voltage VAINT to the fourth node N4.

The storage capacitor CST may include a first electrode for receiving the first driving voltage ELVDD and a second electrode connected to the first node N1. The storage capacitor CST may store the data voltage VDATA.

The light-emitting element EL may include an anode connected to the fourth node N4, and a cathode for receiving a second driving voltage ELVSS. The light-emitting element EL may emit a light based on the driving current generated by the first pixel transistor PT1.

In one or more embodiments, the first pixel transistor PT1, the second pixel transistor PT2, and the fifth to seventh pixel transistors PT5 to PT7 may be implemented as the PMOS transistor, and the third pixel transistor PT3 and the fourth pixel transistor PT4 may be implemented as the NMOS transistor, but the present disclosure is not limited thereto. For example, all of the first to seventh pixel transistors PT1 to PT7 may be implemented as the PMOS transistor. In another example, all of the first to seventh pixel transistors PT1 to PT7 may be implemented as the NMOS transistor.

The pixel PX is illustrated as including seven transistors PT1 to PT7 and one capacitor CST, but the pixel PX is not limited thereto. For example, the pixel PX may include at least two or more transistors and at least one or more capacitors.

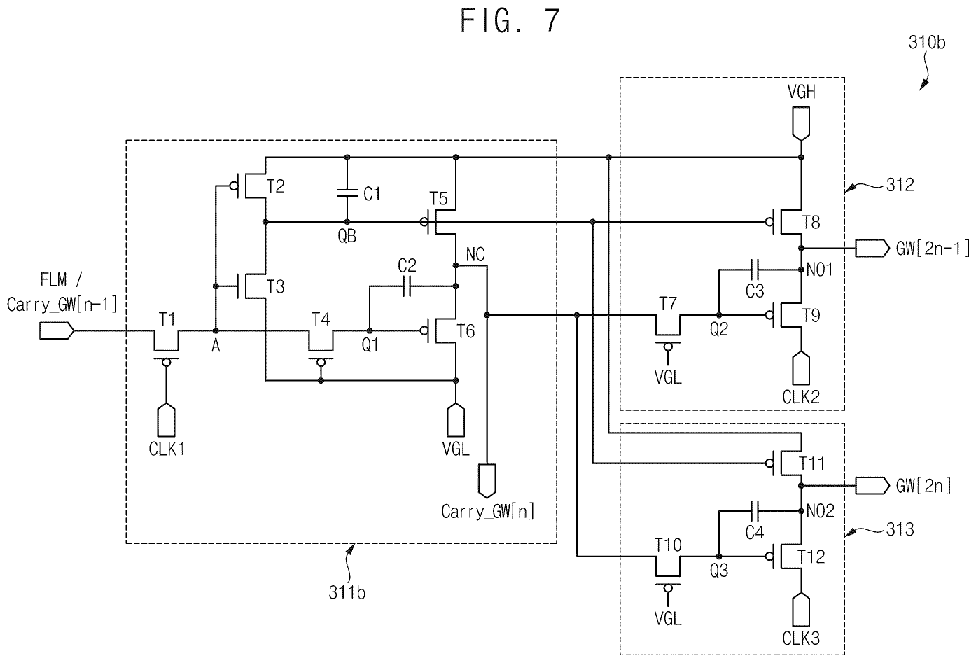

FIG. 7 is a circuit diagram illustrating one or more embodiments of the stage 310 of FIG. 3.

Referring to FIG. 7, a stage 310b may include a control circuit 311b, the first output circuit 312, and the second output circuit 313. The stage 310b is substantially the same as the stage 310a of FIG. 4 except for a connection relationship of a control electrode of the third transistor T3 and an operation of the gate driver 300a. Thus, the same reference numerals will be used to refer to the same or like parts as those described with respect to FIG. 4, and any repetitive explanation concerning the above elements will be omitted.

The third transistor T3 included in the control circuit 311b may include a control electrode connected to the buffer node A, a first electrode connected to the pull-up control node QB, and a second electrode for receiving the second power supply voltage VGL. When the third transistor T3 is turned on in response to the voltage of the buffer node A, the third transistor T3 may transmit the second power supply voltage VGL to the pull-up control node QB.

As the first output circuit 312 and the second output circuit 313 share the control circuit 311b, the display device 1 may decrease the number of control circuits 311b included in the gate driver 300a. As the number of the control circuits 311b included in the gate driver 300a decreases, the number of the transistors included in the gate driver 300a may decrease. In addition, as the number of the transistors included in the gate driver 300a decreases, the power consumption of the display device 1 may decrease.

Further, as the number of the transistors included in the gate driver 300a decreases, the dead space of the display device 1 may decrease. As the dead space of the display device 1 decreases, the ratio W/L of the channel width to the channel length of each of the transistors included in the first output circuit 312 or the second output circuit 313 may increase. Accordingly, the driving current of each of the transistors included in the gate driver 300a may increase.

In addition, as the driving current of each of the transistors included in the gate driver 300a increases, the rising time and the falling time of the gate signal GW output from the gate driver 300a may decrease. Accordingly, each of the transistors included in the gate driver 300a may exactly output the output value, thus the stability of gate driver 300a and the reliability of the gate driver 300a may be improved.

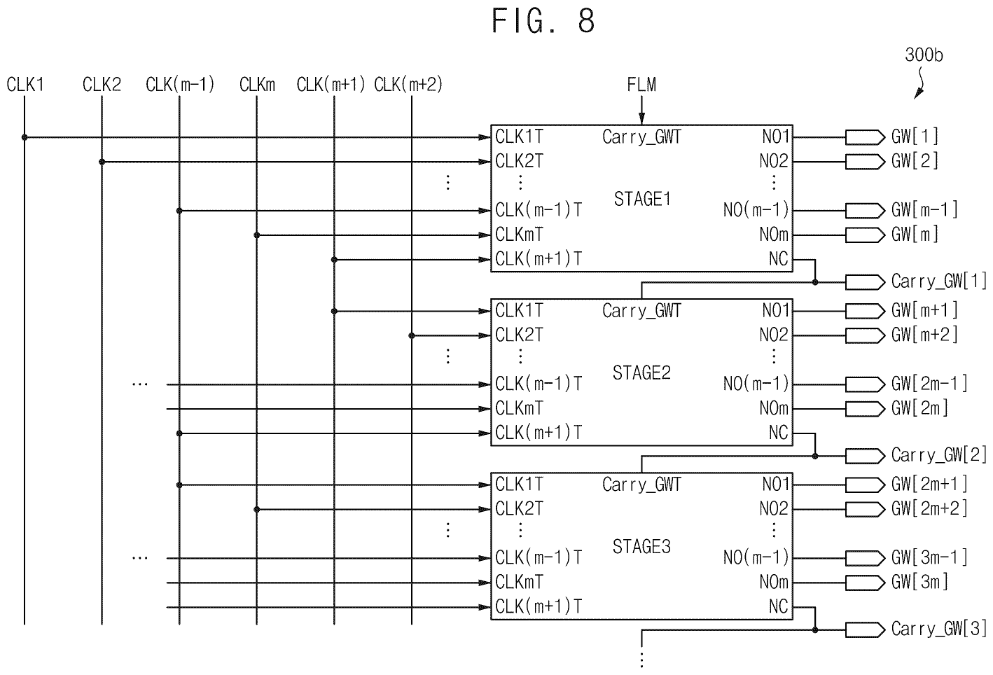

FIG. 8 is a block diagram illustrating one or more embodiments of the gate driver 300 included in the display device of FIG. 1.

Referring to FIG. 8, a gate driver 300b may receive the input signal FLM or Carry_GW, first to (m+2)-th clock signals CLK1, CLK2, . . . , CLK(m+1), and CLK(m+2), where m is an integer greater than or equal to 2, and may include the stages STAGE1, STAGE2, STAGE3, STAGE4, . . . that sequentially output gate signals GW[1], GW[2], GW[3], GW[4], . . . to pixels PX. The input signal FLM or Carry_GW may be the start signal FLM or the carry signal Carry_GW of the previous stage. The first to (m+2)-th clock signals are shown as being applied in the FIG. 8, but the present disclosure is not limited thereto. For example, the gate driver 300b may receive first to (m+1)-th clock signals CLK1, CLK2, . . . , CLK(m+1).

Each of the stages STAGE1, STAGE2, STAGE3, . . . may output the gate signals.

The first stage STAGE1 may output first to m-th gate signals GW[1], GW[2], . . . , GW[m]. For example, the first stage STAGE1 may output the first gate signal GW[1] from the first output node NO1. The first stage STAGE1 may output the second gate signal GW[2] from the second output node NO2. In this way, the first stage STAGE1 may output the m-th gate signal GW[2] from an m-th output node NOm.

The second stage STAGE2 may output (m+1)-th to 2m-th gate signals GW[m+1], GW[m+2], . . . , GW[2m]. For example, the second stage STAGE2 may output the (m+1)-th gate signal GW[m+1] from the first output node NO1. The second stage STAGE2 may output the (m+2) gate signal GW[m+2] from the second output node NO2. In this way, the second stage STAGE2 may output the 2m-th gate signal GW[2m] from the m-th output node NOm.

Each of the stages STAGE1, STAGE2, STAGE3, . . . may output the carry signal Carry_GW.

For example, the first stage STAGE1 may output the first carry signal Carry_GW[1]. For example, the second stage STAGE2 may output the second carry signal Carry_GW[2]. For example, the third stage STAGE3 may output the third carry signal Carry_GW[3].

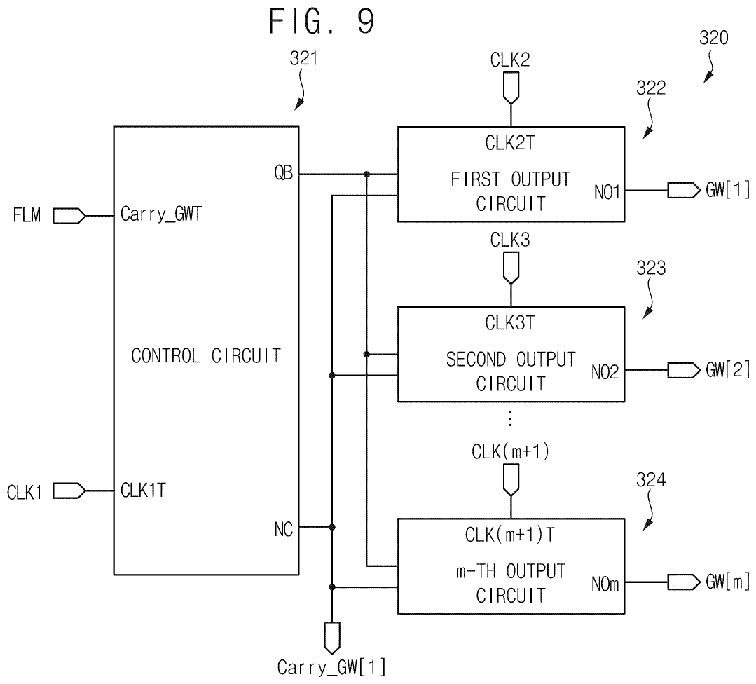

FIG. 9 is a block diagram illustrating a stage 320 included in the gate driver 300b of FIG. 8.

Referring to FIG. 9, the stage 320 may include a control circuit 321 and output circuits 322, 323, and 324. For convenience of explanation, the stage 320 is assumed to be the first stage STAGE1 for receiving the start signal FLM through the input terminal Carry_GWT.

The control circuit 321 may receive the first clock signal CLK1 through the first clock terminal CLK1T. The control circuit 321 may receive the start signal FLM through the input terminal Carry_GWT. The carry output node NC of the control circuit 321 may be connected to the output circuits 322, 323, and 324, and the pull-up control node QB may be connected to the output circuits 322, 323, and 324. The control circuit 321 may output the first carry signal Carry_GW[1] at the carry output node NC.

The first output circuit 312 may receive the second clock signal CLK2 through the second clock terminal CLK2T. The first output circuit 312 may output the first gate signal GW[1] in response to the second clock signal CLK2 applied to the second clock terminal CLK2T, the voltage of the pull-up control node QB, and the voltage of the carry output node NC.

The second output circuit 313 may receive the third clock signal CLK3 through the third clock terminal CLK3T. The second output circuit 313 may output the second gate signal GW[2] in response to the third clock signal CLK3 applied to the third clock terminal CLK3T, the voltage of the pull-up control node QB, and the voltage of the carry output node NC.

Each of the stages, except for the first stage STAGE1, may receive the carry signal Carry_GW of the previous stage through the input terminal Carry_GWT. In addition, each of the clock terminals CLK1T, CLK2T, CLK3T, . . . , CLK(m+1)T of the control circuit 321 and the output circuits 322, 323, and 324 may receive one of the clock signals. For example, each of the clock terminals CLK1T, CLK2T, CLK3T, . . . , CLK(m+1)T of the control circuit 321 and the output circuits 322, 323, and 324 may receive one of the first to (m+1)-th clock signals CLK1, CLK2, . . . , CLK(m+1). For example, each of the clock terminals CLK1T, CLK2T, CLK3T, . . . , CLK(m+2)T of the control circuit 321 and the output circuits 322, 323, and 324 may receive one of the first to (m+2)-th clock signals CLK1, CLK2, . . . , CLK(m+1), and CLK(m+2).

As the output circuits 322, 323, and 324 share the control circuit 321, the display device 1 may decrease the number of control circuits 321 included in the gate driver 300b. As the number of the control circuits 321 included in the gate driver 300b decreases, the number of transistors included in the gate driver 300b may decrease. In addition, as the number of the transistors included in the gate driver 300b decreases, the power consumption of the display device 1 may decrease.

Further, as the number of the transistors included in the gate driver 300b decreases, the dead space of the display device 1 may decrease. As the dead space of the display device 1 decreases, a ratio W/L of a channel width to a channel length of each of the transistors included in each of the output circuits 322, 323, and 324 may increase. Accordingly, a driving current of each of the transistors included in the gate driver 300b may increase.

In addition, as the driving current of each of the transistors included in the gate driver 300b increases, a rising time and a falling time of the gate signal GW output from the gate driver 300b may decrease. Accordingly, each of the transistors included in the gate driver 300b may output an accurate output value, so that stability and reliability of gate driver 300b may be improved.

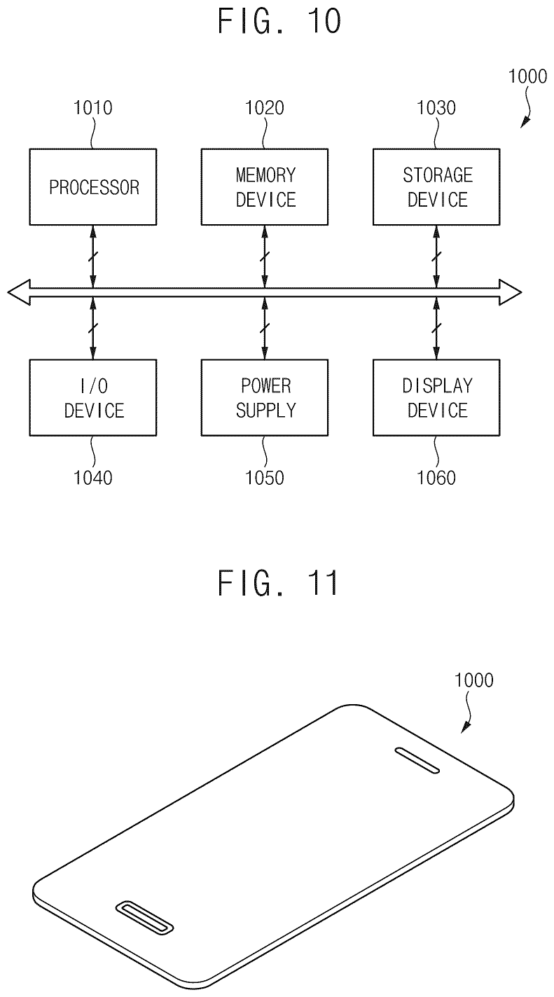

FIG. 10 is a block diagram illustrating an electronic device 1000 according to embodiments, and FIG. 11 is a diagram illustrating one or more embodiments in which the electronic device 1000 of FIG. 10 is implemented as a smart phone.

Referring to FIGS. 10 and 11, the electronic device 1000 may include a processor 1010, a memory device 1020, a storage device 1030, an input/output (I/O) device 1040, a power supply 1050 and a display device 1060. The display device 1060 may be the display device 1 of FIG. 1. In addition, the electronic device 1000 may further include ports for communicating with a video card, a sound card, a memory card, an universal serial bus (USB) device, other electronic device, and the like.

In one or more embodiments, as illustrated in FIG. 11, the electronic device 1000 may be implemented as the smart phone. However, the electronic device 1000 is not limited thereto. For example, the electronic device 1000 may be implemented as a cellular phone, a video phone, a smart pad, a smart watch, a tablet PC, a car navigation system, a computer monitor, a laptop, a head mounted display (HMD) device, and the like.

The processor 1010 may perform various computing functions. The processor 1010 may be a micro processor, a central processing unit (CPU), an application processor (AP), and the like. The processor 1010 may be coupled to other components via an address bus, a control bus, a data bus, and the like. According to one or more embodiments, the processor 1010 may be coupled to an extended bus such as a peripheral component interconnection (PCI) bus.

For example, as shown in FIG. 1, the processor 1010 may output the input image data IMG and the input control signal CONT to the driving controller 200 included in the display device 1 of FIG. 1.

The memory device 1020 may store data for operations of the electronic device 1000. For example, the memory device 1020 may include at least one non-volatile memory device such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, a ferroelectric random access memory (FRAM) device, and the like and/or at least one volatile memory device such as a dynamic random access memory (DRAM) device, a static random access memory (SRAM) device, a mobile DRAM device, and the like.

The storage device 1030 may include a solid state drive (SSD) device, a hard disk drive (HDD) device, a CD-ROM device, and the like.

The I/O device 1040 may include an input device such as a keyboard, a keypad, a touch-pad, a touch-screen, a mouse device, and the like, and an output device such as a speaker, a printer, and the like. In some embodiments, the I/O device 1040 may include the display device 1060.

The power supply 1050 may provide power for operations of the electronic device 1000.

The display device 1060 may be connected to other components through buses or other communication links.

The display device 1060 may include the gate driver 300a, and the gate driver 300a may include the stages STAGE1, STAGE2, STAGE3, STAGE4, . . . that sequentially output gate signals GW[1], GW[2], GW[3], GW[4], . . . to pixels PX. Each of the stages STAGE1, STAGE2, STAGE3, STAGE4, . . . may output two or more gate signals GW. For example, each of the stages STAGE1, STAGE2, STAGE3, STAGE4, . . . included in the gate driver 300a may include the control circuit 311, the first output circuit 312 outputting the first gate signal GW[2n−1], and the second output circuit 313 outputting the second gate signal GW[2n].

As the first output circuit 312 and the second output circuit 313 share the control circuit 311, the display device 1060 may decrease the number of control circuits 311 included in the gate driver 300a. As the number of the control circuits 311 included in the gate driver 300a decreases, the number of the transistors included in the gate driver 300a may decrease. In addition, as the number of the transistors included in the gate driver 300a decreases, the power consumption of the display device 1060 may decrease.

Further, as the number of the transistors included in the gate driver 300a decreases, the dead space of the display device 1060 may decrease. As the dead space of the display device 1060 decreases, the ratio W/L of the channel width to the channel length of each of the transistors included in the first output circuit 312 or the second output circuit 313 may increase. Accordingly, the driving current of each of the transistors included in the gate driver 300a may increase.

In addition, as the driving current of each of the transistors included in the gate driver 300a increases, the rising time and the falling time of the gate signal GW output from the gate driver 300a may decrease. Accordingly, each of the transistors included in the gate driver 300a may output an accurate output value, so that stability and reliability of gate driver 300a may be improved.

The present disclosures may be applied to a display device and an electronic device including the display device. For example, the present disclosures may be applied to a high resolution smart phone, a mobile phone, a smart pad, a smart watch, a tablet computer, a car navigation system, a television, a computer monitor, a laptop, etc.

The foregoing is illustrative of the present disclosure and is not to be construed as limiting thereof. Although a few embodiments of the present disclosure have been described, those skilled in the art will readily appreciate that many modifications are possible in the embodiments without materially departing from the aspects of the present disclosure. Accordingly, all such modifications are intended to be included within the scope of the present disclosure as defined in the claims, with functional equivalents thereof to be included therein. In the claims, means-plus-function clauses are intended to cover the structures described herein as performing the recited function and not only structural equivalents but also equivalent structures. Therefore, it is to be understood that the foregoing is illustrative of the present disclosure and is not to be construed as limited to the specific embodiments disclosed, and that modifications to the disclosed embodiments, as well as other embodiments, are intended to be included within the scope of the appended claims. The present disclosure is defined by the following claims, with equivalents of the claims to be included therein.

What is claimed is:

1. A gate driver comprising:
stages each outputting two or more gate signals,
wherein each of the stages comprises:
a control circuit configured to control a voltage of a pull-up control node and a voltage of a first pull-down control node in response to an input signal and a first clock signal, and configured to output a carry signal at a carry output node in response to the voltage of the pull-up control node and the voltage of the first pull-down control node;
a first output circuit configured to output a first gate signal at a first output node in response to the voltage of the pull-up control node and a voltage of the carry output node; and
a second output circuit configured to output a second gate signal at a second output node in response to the voltage of the pull-up control node and the voltage of the carry output node.

2. The gate driver of claim 1, wherein the control circuit comprises:
a first transistor comprising a control electrode configured to receive the first clock signal, a first electrode configured to receive the input signal, and a second electrode connected to a buffer node;
a second transistor comprising a control electrode connected to the buffer node, a first electrode configured to receive a first power supply voltage, and a second electrode connected to the pull-up control node;
a third transistor comprising a control electrode, a first electrode connected to the pull-up control node, and a second electrode configured to receive a second power supply voltage;
a fourth transistor comprising a control electrode configured to receive the second power supply voltage, a first electrode connected to the buffer node, and a second electrode connected to the first pull-down control node;
a fifth transistor comprising a control electrode connected to the pull-up control node, a first electrode configured to receive the first power supply voltage, and a second electrode connected to the carry output node;
a sixth transistor comprising a control electrode connected to the first pull-down control node, a first electrode connected to the carry output node, and a second electrode configured to receive the second power supply voltage;
a first capacitor comprising a first electrode configured to receive the first power supply voltage, and a second electrode connected to the pull-up control node; and
a second capacitor comprising a first electrode connected to the carry output node, and a second electrode connected to the first pull-down control node.

3. The gate driver of claim 2, wherein the control electrode of the third transistor is connected to the first pull-down control node.

4. The gate driver of claim 2, wherein the control electrode of the third transistor is connected to the buffer node.

5. The gate driver of claim 2, wherein the third transistor comprises an N-channel metal oxide semiconductor (NMOS) transistor.

6. The gate driver of claim 2, wherein the first output circuit comprises:
a seventh transistor comprising a control electrode configured to receive the second power supply voltage, a first electrode connected to the carry output node, and a second electrode connected to a second pull-down control node;
an eighth transistor comprising a control electrode connected to the pull-up control node, a first electrode configured to receive the first power supply voltage, and a second electrode connected to the first output node;
a ninth transistor comprising a control electrode connected to the second pull-down control node, a first electrode connected to the first output node, and a second electrode configured to receive a second clock signal; and
a third capacitor comprising a first electrode connected to the first output node, and a second electrode connected to the second pull-down control node.

7. The gate driver of claim 6, wherein a ratio of a channel width to a channel length of at least one of the seventh transistor, the eighth transistor, or the ninth transistor is different from a ratio of a channel width to a channel length of at least one of the first transistor, the second transistor, the third transistor, the fourth transistor, the fifth transistor, or the sixth transistor.

8. The gate driver of claim 7, wherein the ratio of the channel width to the channel length of the at least one of the seventh transistor, the eighth transistor, or the ninth transistor is greater than the ratio of the channel width to the channel length of the at least one of the first transistor, the second transistor, the third transistor, the fourth transistor, the fifth transistor, or the sixth transistor.

9. The gate driver of claim 2, wherein the second output circuit comprises:
a tenth transistor comprising a control electrode configured to receive the second power supply voltage, a first electrode connected to the carry output node, and a second electrode connected to a third pull-down control node;
an eleventh transistor comprising a control electrode connected to the pull-up control node, a first electrode configured to receive the first power supply voltage, and a second electrode connected to the second output node;
a twelfth transistor comprising a control electrode connected to the third pull-down control node, a first electrode connected to the second output node, and a second electrode configured to receive a third clock signal; and
a fourth capacitor comprising a first electrode connected to the second output node, and a second electrode connected to the third pull-down control node.

10. The gate driver of claim 9, wherein a ratio of a channel width to a channel length of at least one of the tenth transistor, the eleventh transistor, or the twelfth transistor is different from a ratio of a channel width to a channel length of at least one of the first transistor, the second transistor, the third transistor, the fourth transistor, the fifth transistor, or the sixth transistor.

11. The gate driver of claim 10, wherein the ratio of the channel width to the channel length of the at least one of the tenth transistor, the eleventh transistor, or the twelfth transistor is greater than the ratio of the channel width to the channel length of the at least one of the first transistor, the second transistor, the third transistor, the fourth transistor, the fifth transistor, or the sixth transistor.

12. A display device comprising:
a display panel comprising pixels;
a data driver configured to provide data voltages to the display panel;
a gate driver configured to provide gate signals to the display panel; and
a driving controller configured to control the data driver and the gate driver,
wherein the gate driver includes stages each outputting two or more the gate signals.

13. The display device of claim 12, wherein each of the stages comprises:
a control circuit configured to control a voltage of a pull-up control node and a voltage of a first pull-down control node in response to an input signal and a first clock signal, and configured to output a carry signal at a carry output node in response to the voltage of the pull-up control node and the voltage of the first pull-down control node;
a first output circuit configured to output a first gate signal at a first output node in response to the voltage of the pull-up control node and a voltage of the carry output node; and
a second output circuit configured to output a second gate signal at a second output node in response to the voltage of the pull-up control node and the voltage of the carry output node.

14. The display device of claim 13, wherein the control circuit comprises:
a first transistor comprising a control electrode configured to receive the first clock signal, a first electrode configured to receive the input signal, and a second electrode connected to a buffer node;
a second transistor comprising a control electrode connected to the buffer node, a first electrode configured to receive a first power supply voltage, and a second electrode connected to the pull-up control node;
a third transistor comprising a control electrode, a first electrode connected to the pull-up control node, and a second electrode configured to receive a second power supply voltage;
a fourth transistor comprising a control electrode configured to receive the second power supply voltage, a first electrode connected to the buffer node, and a second electrode connected to the first pull-down control node;
a fifth transistor comprising a control electrode connected to the pull-up control node, a first electrode configured to receive the first power supply voltage, and a second electrode connected to the carry output node;
a sixth transistor comprising a control electrode connected to the first pull-down control node, a first electrode connected to the carry output node, and a second electrode configured to receive the second power supply voltage;
a first capacitor comprising a first electrode configured to receive the first power supply voltage, and a second electrode connected to the pull-up control node; and
a second capacitor comprising a first electrode connected to the carry output node, and a second electrode connected to the first pull-down control node.

15. The display device of claim 14, wherein the control electrode of the third transistor is connected to the first pull-down control node.

16. The display device of claim 14, wherein the first output circuit comprises:
a seventh transistor comprising a control electrode configured to receive the second power supply voltage, a first electrode connected to the carry output node, and a second electrode connected to a second pull-down control node;
an eighth transistor comprising a control electrode connected to the pull-up control node, a first electrode configured to receive the first power supply voltage, and a second electrode connected to the first output node;
a ninth transistor comprising a control electrode connected to the second pull-down control node, a first electrode connected to the first output node, and a second electrode configured to receive a second clock signal; and
a third capacitor comprising a first electrode connected to the first output node and a second electrode connected to the second pull-down control node.

17. The display device of claim 16, wherein a ratio of a channel width to a channel length of at least one of the seventh transistor, the eighth transistor, or the ninth transistor is different from a ratio of a channel width to a channel length of at least one of the first transistor, the second transistor, the third transistor, the fourth transistor, the fifth transistor, or the sixth transistor.

18. The display device of claim 14, wherein the second output circuit comprises:
a tenth transistor comprising a control electrode configured to receive the second power supply voltage, a first electrode connected to the carry output node, and a second electrode connected to a third pull-down control node;
an eleventh transistor comprising a control electrode connected to the pull-up control node, a first electrode configured to receive the first power supply voltage, and a second electrode connected to the second output node;
a twelfth transistor comprising a control electrode connected to the third pull-down control node, a first electrode connected to the second output node, and a second electrode configured to receive a third clock signal; and
a fourth capacitor comprising a first electrode connected to the second output node, and a second electrode connected to the third pull-down control node.

19. The display device of claim 18, wherein a ratio of a channel width to a channel length of at least one of the tenth transistor, the eleventh transistor, or the twelfth transistor is different from a ratio of a channel width to a channel length of at least one of the first transistor, the second transistor, the third transistor, the fourth transistor, the fifth transistor, or the sixth transistor.

20. An electronic device comprising:
a processor configured to output an input control signal and input image data;
a display panel comprising pixels;
a data driver configured to provide data voltages to the display panel;
a gate driver configured to provide gate signals to the display panel; and
a driving controller configured to control the data driver and the gate driver based on the input control signal and the input image data,
wherein the gate driver comprises stages each outputting two or more the gate signals, and
wherein each of the stages comprises:
a control circuit configured to control a voltage of a pull-up control node and a voltage of a first pull-down control node in response to an input signal and a first clock signal, and configured to output a carry signal at a carry output node in response to the voltage of the pull-up control node and the voltage of the first pull-down control node;
a first output circuit configured to output a first gate signal at a first output node in response to the voltage of the pull-up control node and a voltage of the carry output node; and
a second output circuit configured to output a second gate signal at a second output node in response to the voltage of the pull-up control node and the voltage of the carry output node.
